(19) United States
(12) Patent Application Publication
(10) Pub. No.: US 2020/0057376 A1
(43) Pub. Date: Feb. 20, 2020

(54) LITHOGRAPHY SYSTEM AND LITHOGRAPHY METHOD

(71) Applicant: TAIWAN SEMICONDUCTOR MANUFACTURING CO., LTD., Hsinchu (TW)

(72) Inventors: Chun-Chia HSU, Kaohsiung City (TW); Chi YANG, Taichung City (TW); Shang-Chieh CHIEN, New Taipei City (TW); Li-Jui CHEN, Hsinchu City (TW); Po-Chung CHENG, Chiayi County (TW)

(21) Appl. No.: 16/102,887

(22) Filed: Aug. 14, 2018

(51) Int. Cl. G03F 7/20

(52) U.S. Cl. CPC G03F 7/2053; G03F 7/70033; G03F 7/70141; G03F 7/7085

(57) ABSTRACT

A lithography method includes outputting, by an optical alignment sensor in a scanner system, a first signal in response to a light signal received by the optical alignment sensor; controlling, by a controller, a trajectory of a droplet in a light source system according to the first signal feedback to the controller; and irradiating the droplet by a drive laser to output a light beam from the light source system to the scanner system.

### BACKGROUND

Semiconductor devices have been more and more miniaturized. The semiconductor devices are mass-produced by repeatedly applying a photolithography process to form different layers of material.

In a photolithography process, a photomask having a pattern is irradiated with light to transfer the pattern onto a photosensitive coating on a semiconductor substrate (hereinafter, referred to as “wafer”) via a reduction optical system. In recent years, photolithography that uses extreme ultraviolet (EUV) light has been in development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a light source system of a lithography system, in accordance with some embodiments of the present disclosure.

FIG. 2 is a schematic diagram illustrating operations of a lithography system including the light source system and a scanner system, in accordance with some embodiments of the present disclosure.

FIG. 3 is a schematic diagram illustrating operations of positioning of the lithography system, in accordance with some embodiments of the present disclosure.

FIG. 4 is a schematic diagram illustrating operations of pointing of the lithography system, in accordance with some embodiments of the present disclosure.

FIG. 5 is a diagram illustrating operations of the light source system, in accordance with some embodiments of the present disclosure.

FIG. 6A is a flow chart of a lithography method, in accordance with some embodiments of the present disclosure.

FIG. 6B is a detailed flow chart of an operation of the lithography method shown in FIG. 6A, in accordance with some embodiments of the present disclosure.

FIG. 7 is a flow chart of a lithography method, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

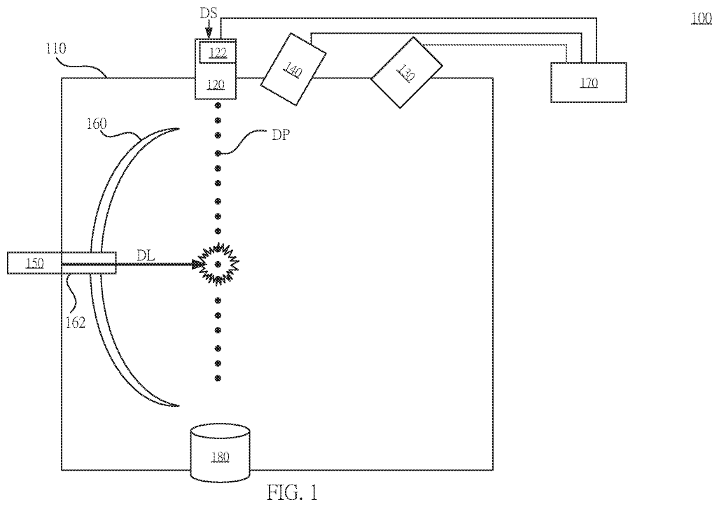

Reference is now made to FIG. 1. FIG. 1 is a schematic diagram of a light source system 100 of a lithography system, in accordance with some embodiments of the present disclosure. As illustratively shown in FIG. 1, in some embodiments, the light source system 100 includes a chamber 110, a droplet generator 120, a line laser module (LLM) 130, a droplet steering camera 140, a drive laser generator 150, a collector mirror 160, a controller 170, and a droplet catcher 180. The light source system 100 is configured to produce light within an extreme ultraviolet (EUV) range. Methods for generating EUV light include converting a target material from a liquid state into plasma. In a laser produced plasma (LPP) method, the plasma is produced by irradiating the target material having a EUV emitting element with a drive laser beam, which will be discussed in the following paragraphs.

In some embodiments, in structural, the droplet generator 120, the line laser module 130, the droplet steering camera 140 and the droplet catcher 180 are mounted to the chamber 110 and work as a droplet generator steering system (DGSS) with co-operation with the controller 170. In some embodiments, the chamber 110 includes a side wall that defines an opening to an interior of the chamber 110. In some embodiments, the chamber 110 includes a vacuum vessel which is sealed during the use, such that an interior space of the vacuum vessel is maintained as a vacuum.

The interior of the chamber 110 is configured to receive a light beam produced from the drive laser generator 150, and droplets DP from the droplet generator 120. The droplets include a material which produces emitted light when converted to plasma by the light beam from the drive laser generator 150. In some embodiments, the emitted light includes light within an extreme ultraviolet (EUV) range.

In this example, the droplet generator 120 is configured to deliver and direct a mixture in the form of liquid droplets, a liquid stream, solid particles or clusters, solid particles contained within liquid droplets or solid particles contained within a liquid stream. In some embodiments, the droplets DP delivered by the droplet generator 120 include material such as, for example, water, tin, lithium, or xenon when converted to a plasma state, has an emission line in the EUV range. Other suitable materials are within the contemplated scope of the disclosure.

For example, the element tin can be used as pure tin (Sn); as a tin compound, for example, SnBr4, SnBr2, SnH4; as a tin alloy, for example, tin-gallium alloys, tin-indium alloys, tin-indium-gallium alloys, or any combination of these alloys. In some embodiments, impurities such as non-target particles are also included in the mixture. Accordingly, the droplets DP are delivered by the droplet generator 120 into an interior of the chamber 110.

The drive laser generator 150 is configured to produce drive laser DL which passes through the aperture 162 of the collector mirror 160 into the chamber 110. In some embodiments, the drive laser generator 150 includes a driving laser system which produces the drive laser DL. The drive laser DL may be delivered via a transport system configured to modify and steer the drive laser DL according to actual needs and focus the drive laser DL to a target region in the interior of the chamber 110. In some embodiments, the driving laser system includes one or more optical amplifiers, lasers, and/or lamps for providing pulses. In some embodiments, optical amplifiers respectively include a gain medium capable of optically amplifying wavelength at a high gain, an excitation source, and internal optics.

Accordingly, the plasma with the emission line in the EUV range is produced by irradiating the material in the form of the droplets with the amplified drive laser DL when the droplets DP delivered by the droplet generator 120 reaches the target region. The EUV light, for example, electromagnetic radiation having wavelengths of about 50 nm or less (also sometimes referred to as soft x-rays), and including light at a wavelength of about 13 nm, is used in photolithography processes to produce extremely small features in substrates, for example, silicon wafers. Other suitable wavelengths for the EUV light are within the contemplated scope of the disclosure.

In structural, the controller 170 is electrically coupled to the droplet generator 120, the line laser module 130, and the droplet steering camera 140. In some embodiments, the controller 170 is further electrically coupled to the drive laser generator 150. The controller 170 is configured to control the droplet generator 120 by outputting a driving signal DS to the droplet generator 120 in order to adjust the movement of the droplet generator 120. Therefore, the droplet generator 120 is operable in response to the driving signal DS from the controller 170 to adjust and modify the release of the droplets DP to steer the droplets DP arriving at the target region. In other words, the droplet generator 120 is configured to steer the trajectory of the droplet DP. For example, in some embodiments, a motor 122 is arranged in the droplet generator 120 and driven in response to the driving signal DS. The controller 170 outputs the driving signal DS to drive the motor 122.

The droplet catcher 180 is substantially aligned to the droplet path, and configured to catch droplets DP that have passed the target region for EUV production.

The configurations and implementations of the light source system 100 are given for illustrative purposes only. Various configurations and implementations of the light source system 100 are within the contemplated scope of the present disclosure.

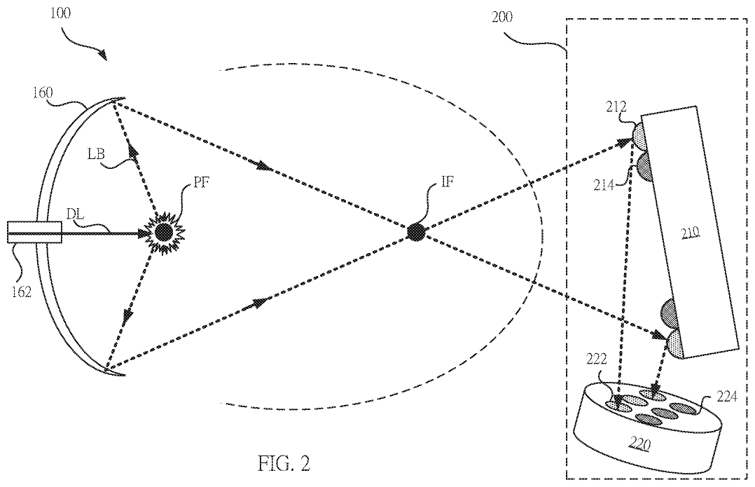

Reference is made to FIG. 2. FIG. 2 is a schematic diagram illustrating operations of a lithography system including the light source system 100 and a scanner system 200, in accordance with some embodiments of the present disclosure. For ease of understanding, with respect to the embodiments of FIG. 1, like elements in FIG. 2 are designated with the same reference numbers.

As illustratively shown in FIG. 2, in some embodiments, the target region mentioned above, also referred as an irradiation site, is configured to be located at a primary focus position PF of the collector mirror 160 arranged in the chamber 110.

In some embodiments, the collector mirror 160 includes the aperture 162 to allow the drive laser DL to pass through and reach the target region. The collector mirror 160 may be, for example, an ellipsoidal mirror having a reflective interior surface. Alternatively stated, the shape of collector mirror 160 may include a portion of an ellipsoid. The collector mirror 160 has a primary focus position PF at the target region and an intermediate focus position IF. After emitted at the primary focus position PF, the light beam LB is firstly collected by the collector mirror 160 and then passing through the intermediate focus IF to the scanner system 200.

In some embodiments, the scanner system 200 contains pods of wafers to be exposed to the EUV light, with a portion of the pod containing wafers currently being irradiated being located at a focus of the EUV light.

As illustratively shown in FIG. 2, in some embodiments, the scanner system 200 includes a field facet mirror 210 and an optical alignment sensor 220, in which optical alignment sensor 220 is applied in an optical alignment system illuminator to source (OASIS) to perform optical alignment. The field facet mirror 210 includes one or more pinhole mirrors 212 and one or more IF mirrors 214. The optical alignment sensor 220 includes one or more pinhole spots 222 and one or more intermediate focus spots 224. The light beam LB outputted by the light source system 100 impinges on the field facet mirror 210 in the scanner system 200, which will be described in detail below.

In some embodiments, the field facet mirror 210 provides uniform illumination of the object field and guides large faction of the light beam LB produced by the light source system 100 to the object field. In this example, the field facet mirror 210 is configured to reflect the light beam LB to the optical alignment sensor 220. The optical alignment sensor 220 is configured to feedback one or more signals to the controller 170 to achieve positioning and pointing of the light beam LB.

As used herein, the term “pinhole mirror” is intended to mean a radiation screen having a surface that is sufficiently smooth to produce an image by specular reflection and a cavity that extends through a screen such that radiation in the UV, VIS or IR regions of the spectrum can pass. Specular reflection occurs when parallel rays of incident radiation, reflected according to the laws of reflection, are reflected substantially parallel to each other at a surface. The laws of reflection hold that the angle of incidence is substantially equal to the angle of reflection and the incident ray, reflected ray, and substantially normal to the rays are coplanar. Diffuse reflection occurs when parallel incident rays are not parallel when reflected at a surface according to the laws of reflection, for example, due to irregularity in the surface. The term includes a cavity having, for example, a width, diameter or major axis of about 1.5 mm or less, 1.2 mm or less, 1.0 mm or less, 0.8 mm or less, 0.6 mm or less, 0.4 mm or less, 0.2 mm or less, or 0.1 mm or less. The term is intended to include a cavity containing any material transparent to irradiation in the UV, VIS or IR regions of the spectrum including, for example, air, glass, or quartz. Thus, in some embodiments, a pinhole mirror is a transparent substrate having a metallic coating where the coating contains a hole and the hole does not pass through the transparent substrate. A cavity contains a material that is selectively transparent to irradiation of a particular wavelength or wavelengths such as a filter material. A cavity included in the term has any cross sectional shape including, for example, circular, elliptical, or square and has uniform or non-uniform cross sectional dimensions along the axis that runs through the center of the cavity from the front to the back of the screen material. An example, of a cavity with uniform cross sectional dimensions along the axis that runs through the center of the cavity is a cylindrical pin hole. Alternatively, a cavity has non-uniform cross sectional dimensions along the axis that runs through the cavity such as that of a conical cavity.

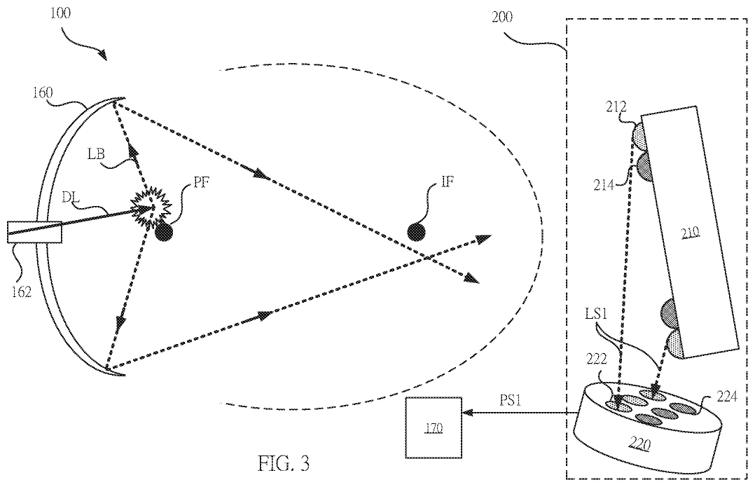

Reference is made to FIG. 3. FIG. 3 is a schematic diagram illustrating operations of positioning, in accordance with some embodiments of the present disclosure. For ease of understanding, with respect to the embodiments of FIG. 2, like elements in FIG. 3 are designated with the same reference numbers. As illustratively shown in FIG. 3, the optical alignment sensor 220 outputs a corresponding positioning signal PS1 back to the controller 170 in the light source system 100 in response to light beam received by the one or more pinhole spots 222. Accordingly, the controller 170 is configured to control the droplet DP passing through the primary focus position PF of the collector mirror 160 according to the light beam received by the one or more pinhole spots 222 on the optical alignment sensor 220.

If the irradiation site shifts away from the primary focus position PF, the light signal LS1 reflected by the one or more pinhole mirrors 212 and received by the one or more pinhole spots 222 decreases, and the optical alignment sensor 220 outputs the positioning signal PS1 back to the controller 170 in order to correct the error of the position of the irradiation site.

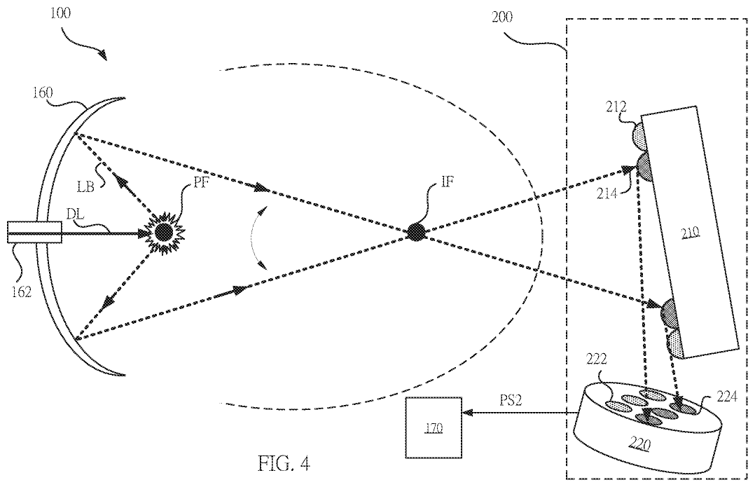

Reference is made to FIG. 4. FIG. 4 is a schematic diagram illustrating operations of pointing, in accordance with some embodiments of the present disclosure. For ease of understanding, with respect to the embodiments of FIG. 2, like elements in FIG. 4 are designated with the same reference numbers. As illustratively shown in FIG. 4, similarly, in some embodiments, the optical alignment sensor 220 may output a corresponding pointing signal PS2 back to the controller 170 in the light source system 100 in response to light beam reflected by the one or more IF mirrors 214 and received by the one or more intermediate focus spots 224. Accordingly, the controller 170 is configured to control the light beam LB passing through the intermediate focus position IF of the collector mirror 160 according to the light beam LB received by one or more intermediate focus spots 224 on the optical alignment sensor 220.

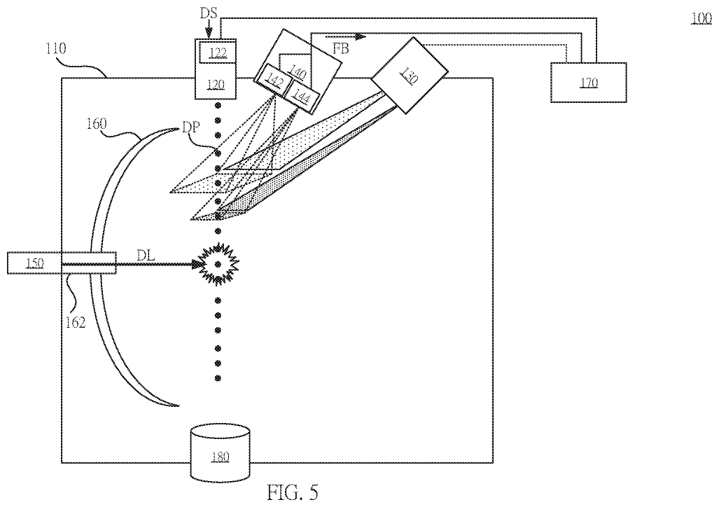

Reference is made to FIG. 5. FIG. 5 is a diagram illustrating operations of the light source system 100, in accordance with some embodiments of the present disclosure. For ease of understanding, with respect to the embodiments of FIG. 1, like elements in FIG. 5 are designated with the same reference numbers. As illustratively shown in FIG. 5, the line laser module 130 is configured to generate a light curtain in the chamber 110. For example, in some embodiments, the line laser module 130 generates the light at the wavelength of about 820 nm. When the droplet DP passes through the light curtain generated by the line laser module 130, the light curtain is disturbed. Alternatively stated, when the droplet DP passes through the light curtain, a flash is generated by the reflection of the laser light of the light curtain from the droplet DP.

The droplet steering camera 140 is configured to image the light curtain as the droplet DP passing through the light curtain to obtain an image. Location of the flash is correspondingly detected to determine the trajectory of the droplets DP, and a feedback signal FB is sent to the controller 170 to redirect the output of the droplet generator 120 to keep the droplets DP on a trajectory that carries them to the target region for irradiation.

Accordingly, by analyzing the image of the droplets DP, whether the droplets DP are accurately directed within a target direction through the target region is determined by the droplet steering camera 140. The controller 170 is configured to steer and control the trajectory of the droplets DP correspondingly based on the data of the image if the trajectory of the droplets DP is incorrect.

In some embodiments, two or more light curtains are generated by the line laser module 130. In this example, the droplet steering camera 140 includes a coarse droplet steering camera (CDSC) unit 142 and a fine droplet steering camera (FDSC) unit 144. The coarse droplet steering camera (CDSC) unit 142 is applied to perform a coarse control with the flash from a first light curtain for steering, and the fine droplet steering camera (FDSC) unit 144 is applied to perform a fine control with the flash from a second light curtain for steering, in order to provide further corrections of the droplet trajectory.

In some embodiments, the temperature of the chamber 110 changes following the thermal cycle. Correspondingly, the thermal expansion occurs to the chamber 110, and the position and mounting of the droplet steering camera 140 located in the chamber 110 change with the increasing temperature. When the position of the droplet steering camera 140 varies, the controller 170 mis-compensates the tilt of the trajectory of the droplets DP due to the change in the image captured by the droplet steering camera 140. Accordingly, the irradiation site where the light beam strikes to the droplets DP shift away from the original target region, which induces power lost due to the power of the EUV light is clipped.

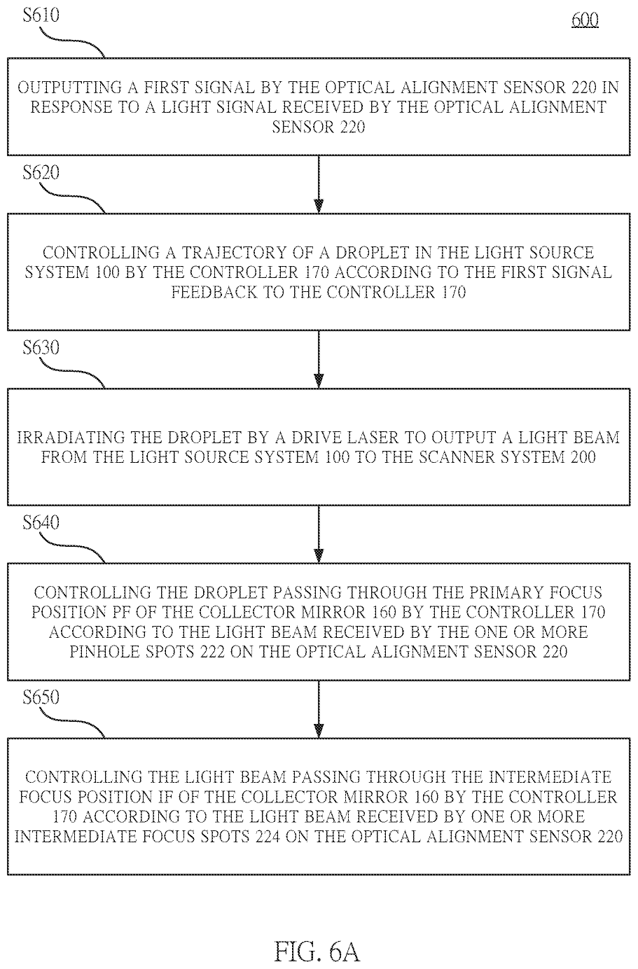

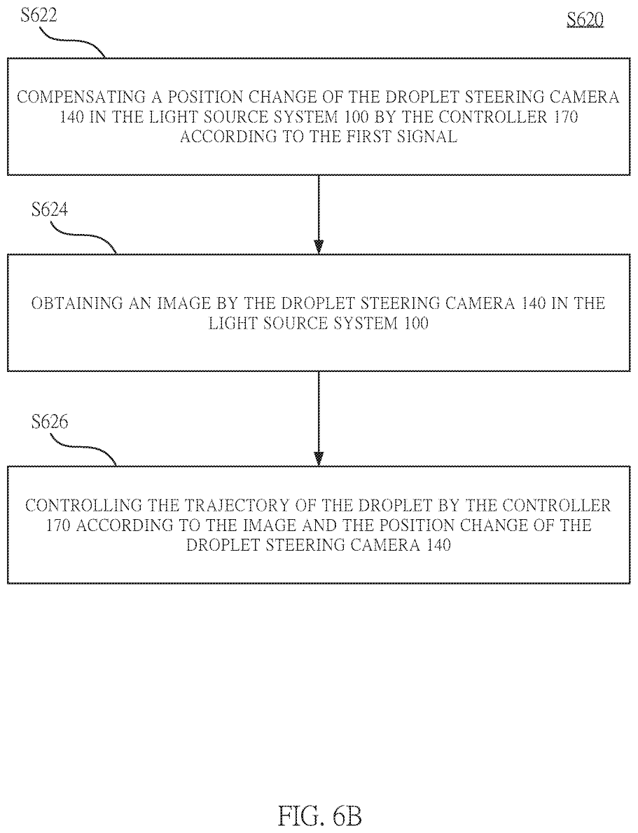

Reference is now made to FIG. 6A and FIG. 6B. FIG. 6A is a flow chart of a lithography method 600, in accordance with some embodiments of the present disclosure. FIG. 6B is a detailed flow chart of an operation S620, in accordance with some embodiments of the present disclosure. For better understanding of the present disclosure, the lithography method 600 is discussed in relation to the embodiments shown in FIGS. 1-5, but is not limited thereto. In some embodiments, the lithography method 600 includes operations S610, S620, S630, S640, and S650.

In operation S610, a first signal is outputted by the optical alignment sensor 220 in response to a light signal LS1 received by the optical alignment sensor 220. When the controller 170 erroneously adjusts the trajectory of the droplets DP due to the change of the position of the droplet steering camera 140 during the thermal expansion of the chamber 110, the irradiation site shifts away from the original primary focus position PF. The light beam LB is reflected by the field facet mirror 210 to the optical alignment sensor 220.

Accordingly, the light signal received by the optical alignment sensor 220 changes. The optical alignment sensor 220 is configured to detecting the light signal LS1 according to the light beam received by the one or more pinhole spots 222 on the optical alignment sensor 220 as illustratively shown in FIG. 3. Then, the optical alignment sensor 220 is configured to output the first signal PS1 according to the light beam received by the one or more pinhole spots 222 on the optical alignment sensor 220. Therefore, the erroneous adjustment of the droplet generator steering system is able to be sensed and detected by the optical alignment sensor 220 based on the light signal LS1 received by the one or more pinhole spots 222.

In operation S620, a trajectory of a droplet DP in the light source system 100 is controlled by the controller 170 according to the first signal feedback to the controller 170. As shown in FIG. 6B, in some embodiments, the operation of controlling the trajectory of the droplet DP in operation S620 includes operations S622, S624, and S626.

In operation S622, a position change of the droplet steering camera 140 in the light source system 100 is compensated by the controller 170 according to the first signal.

In operation S624, an image is obtained by the droplet steering camera 140 in the light source system 100. As described in the embodiments of FIG. 1, in some embodiments, the operation of the droplet steering camera 140 obtaining the image includes controlling the line laser module 130 to generate the light curtain in the chamber 110 of the light source system 100, and controlling the droplet steering camera 140 to image the light curtain as the droplet DP passing through the light curtain to obtain the image.

In operation S626, the trajectory of the droplet DP is controlled by the controller 170 according to the image and the position change of the droplet steering camera 140.

In some embodiments, during the operation S626, the controller 170 is configured to determine the trajectory of the droplet DP according to the image and the position change of the droplet steering camera 140. After the trajectory of the droplet DP is obtained, the controller 170 computes a droplet position error according to the trajectory of the droplet DP, and outputs the driving signal DS in response to the droplet position error to drive the motor 122 in the droplet generator 120 of the light source system 100 to steer the trajectory of the droplet DP.

Alternatively stated, when the droplet generator steering system performs the feedback control to keep the droplets DP in the fixed position by using the droplet steering camera 140 to monitor the droplets DP, the error resulted from the position change of the droplet steering camera 140 is taken into account. The controller 170 computes the position change of the droplet steering camera 140 according to the light signal LS1 received by the optical alignment sensor 220, and then determines the trajectory of the droplet DP in the light source system 100 according to the image and the position change of the droplet steering camera 140.

Thus, in the thermal cycle, the trajectory of the droplets DP is controlled and steered properly and directed to the target region around the primary focus position PF of the collector mirror 160, and the power loss due to the mis-compensation in response to the change in the image captured by the droplet steering camera 140 is avoided.

In operation S630, the drive laser produced from the drive laser generator 150 irradiates the droplet DP to output a light beam from the light source system 100 to the scanner system 200.

In operation S640, the controller 170 is configured to control the droplet DP passing through the primary focus position PF of the collector mirror 160 in the light source system 100 according to the light beam received by the one or more pinhole spots 222 on the optical alignment sensor 220.

In operation S650, the controller 170 is configured to control the light beam passing through the intermediate focus position IF of the collector mirror 160 in the light source system 100 according to the light beam received by one or more intermediate focus spots 224 on the optical alignment sensor 220.

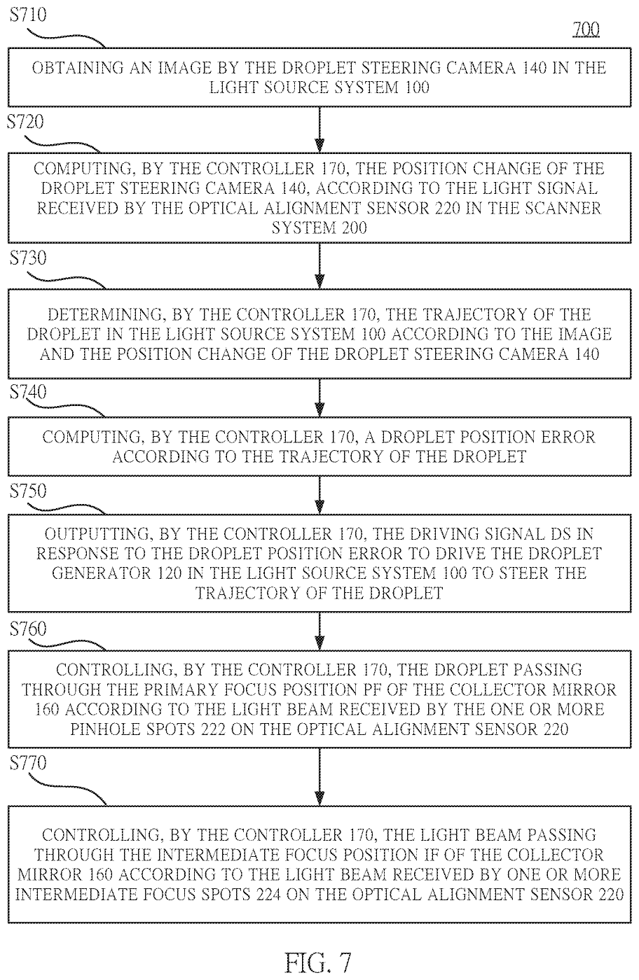

Reference is now made to FIG. 7. FIG. 7 is a flow chart of a lithography method 700, in accordance with some embodiments of the present disclosure. For better understanding of the present disclosure, the lithography method 700 is discussed in relation to the embodiments shown in FIGS. 1-5, but is not limited thereto. In some embodiments, the lithography method 700 includes operations S710, S720, S730, S740, S750, S760, and S770.

In operation S710, the droplet steering camera 140 is configured to obtaining an image in the light source system 100. For example, the line laser module 130 generates the light curtain in the chamber 110 of the light source system 100, and the droplet steering camera 140 is configured to image the light curtain as the droplet DP passing through the light curtain to obtain the image.

In operation S720, the controller 170 is configured to compute the position change of the droplet steering camera 140, according to the light signal received by the optical alignment sensor 220 in the scanner system 200. For example, the field facet mirror 210 in the scanner system 200 reflects the light beam to the optical alignment sensor 220. The optical alignment sensor 220 detects the light signal LS1 received by the optical alignment sensor 220 according to the light beam received by one or more pinhole spots 222 on the optical alignment sensor 220, and output a first signal PS1 to the controller 170 in response to the light signal LS1 received by the optical alignment sensor 220. Thus, the controller 170 may compute the position change of the droplet steering camera 140, according to the first signal.

In operation S730, the controller 170 is configured to determine the trajectory of the droplet DP in the light source system 100 according to the image and the position change of the droplet steering camera 140.

In operation S740, the controller 170 is configured to compute a droplet position error according to the trajectory of the droplet DP.

In operation S750, the controller 170 is configured to output the driving signal DS in response to the droplet position error to drive the droplet generator 120 in the light source system 100 to steer the trajectory of the droplet DP.

Similar to the operations S640 and S650 in the lithography method 600, in the operation S760, the controller 170 is configured to control the droplet DP passing through the primary focus position PF of the collector mirror 160 in the light source system 100 according to the light beam received by the one or more pinhole spots 222 on the optical alignment sensor 220. In the operation S770, the controller 170 is configured to control the light beam passing through the intermediate focus position IF of the collector mirror 160 in the light source system 100 according to the light beam received by one or more intermediate focus spots 224 on the optical alignment sensor 220.

Although a single droplet DP is taken as an example in the lithography methods 600 and 700, in practice, the droplet generator 120 generates droplets DP continuously as mentioned above. Since there is a sequential series of droplets DP, a sequential series of images are detected, and the drive laser DL produced by the drive laser generator 150 irradiates a series of droplets DP at the irradiation site to create the EUV plasma.

In addition, it is noted that in the operations of the abovementioned lithography methods 600 and/or 700, no particular sequence is required unless otherwise specified. Moreover, the operations may also be performed simultaneously or the execution times thereof may at least partially overlap. Furthermore, the operations of the lithography methods 600 and/or 700 may be added to, replaced, and/or eliminated as appropriate, in accordance with various embodiments of the present disclosure.

As described above, in various embodiments, by outputting the signal from the optical alignment sensor 220 in the scanner system 200 back to the controller 170 in the light source system 100, under the condition that the position of the droplet steering camera 140 changes, the trajectory of the droplet DP in the light source system 100 is still properly controlled. In other words, the signal from the OASIS system is feedback to the DGSS system to measure whether the beam drift occurs. When the beam drift is detected, the DGSS system compensates correspondingly to steer the droplets DP to the correct position. Thus, the intermediate focus position for the light beam is ensured. Accordingly, the wafer per hour (WPH) of the system increases, and the throughput of the manufacturing process is improved.

In some embodiments, a lithography method is disclosed that includes: outputting, by an optical alignment sensor in a scanner system, a first signal in response to a light signal received by the optical alignment sensor; controlling, by a controller, a trajectory of a droplet in a light source system according to the first signal feedback to the controller; and irradiating the droplet by a drive laser to output a light beam from the light source system to the scanner system.

In some embodiments, controlling the trajectory of the droplet includes: compensating, by the controller, a position change of a camera in the light source system according to the first signal; obtaining an image by the camera in the light source system; and controlling, by the controller, the trajectory of the droplet according to the image and the position change of the camera.

In some embodiments, obtaining the image by the camera includes: generating, by a line laser module, a light curtain in a chamber of the light source system; and imaging, by the camera, the light curtain as the droplet passing through the light curtain to obtain the image.

In some embodiments, controlling the trajectory of the droplet includes: determining, by the controller, the trajectory of the droplet according to the image and the position change of the camera; computing, by the controller, a droplet position error according to the trajectory of the droplet; and outputting, by the controller, a driving signal in response to the droplet position error to drive a droplet generator in the light source system to steer the trajectory of the droplet.

In some embodiments, the lithography method further includes: reflecting the light beam, by a field facet mirror in the scanner system, to the optical alignment sensor; and detecting the light signal received by the optical alignment sensor according to the light beam received by one or more pinhole spots on the optical alignment sensor.

In some embodiments, the lithography method further includes: controlling, by the controller, the droplet passing through a primary focus position of a collector mirror in the light source system according to the light beam received by the one or more pinhole spots on the optical alignment sensor.

In some embodiments, the lithography method further includes: controlling, by the controller, the light beam passing through an intermediate focus position of the collector mirror in the light source system according to the light beam received by one or more intermediate focus spots on the optical alignment sensor.

Also disclosed is a lithography method, including: obtaining an image by a camera in a light source system; computing, by a controller, a position change of the camera, according to a light signal received by an optical alignment sensor in a scanner system; and determining, by the controller, a trajectory of a droplet in the light source system according to the image and the position change of the camera.

In some embodiments, obtaining the image includes: generating, by a line laser module, a light curtain in a chamber of the light source system; and imaging, by the camera, the light curtain as the droplet passing through the light curtain to obtain the image.

In some embodiments, the lithography method further includes: computing, by the controller, a droplet position error according to the trajectory of the droplet; and outputting, by the controller, a driving signal in response to the droplet position error to drive a droplet generator in the light source system to steer the trajectory of the droplet.

In some embodiments, the lithography method further includes: reflecting a light beam by a field facet mirror in the scanner system to the optical alignment sensor; and detecting, by the optical alignment sensor, the light signal received by the optical alignment sensor according to the light beam received by one or more pinhole spots on the optical alignment sensor.

In some embodiments, the lithography method further includes: outputting, by the optical alignment sensor, a first signal to the controller in response to the light signal received by the optical alignment sensor; and computing, by the controller, the position change of the camera, according to the first signal.

In some embodiments, the lithography method further includes: controlling, by the controller, the droplet passing through a primary focus position of a collector mirror in the light source system according to the light beam received by the one or more pinhole spots on the optical alignment sensor.

In some embodiments, the lithography method further includes: controlling, by the controller, the light beam passing through an intermediate focus position of the collector mirror in the light source system according to the light beam received by one or more intermediate focus spots on the optical alignment sensor.

Also disclosed is a lithography system that includes a camera, an optical alignment sensor, and a controller. The camera is configured to obtain an image of a droplet in a chamber. The optical alignment sensor is configured to output a first signal in response to a light signal received by the optical alignment sensor. The controller is configured to compute a position change of the camera according to the first signal, and determine a trajectory of the droplet in the chamber according to the image and the position change of the camera.

In some embodiments, the lithography system further includes a line laser module configured to generate a light curtain in the chamber. The camera is configured to image the light curtain as the droplet passing through the light curtain to obtain the image.

In some embodiments, the lithography system further includes a droplet generator configured to steer the trajectory of the droplet. The controller is further configured to compute a droplet position error according to the trajectory of the droplet, and output a driving signal in response to the droplet position error to drive the droplet generator.

In some embodiments, the lithography system further includes a field facet mirror configured to reflect a light beam to the optical alignment sensor. The optical alignment sensor is configured to output the first signal according to the light beam received by one or more pinhole spots on the optical alignment sensor.

In some embodiments, the lithography system further includes a collector mirror in the chamber. The controller is configured to control the droplet passing through a primary focus position of the collector mirror according to the light beam received by the one or more pinhole spots on the optical alignment sensor.

In some embodiments, the controller is further configured to control the light beam passing through an intermediate focus position of the collector mirror according to the light beam received by one or more intermediate focus spots on the optical alignment sensor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A lithography method, comprising:
outputting, by an optical alignment sensor in a scanner system, a first signal in response to a light signal received by the optical alignment sensor;
controlling, by a controller, a trajectory of a droplet in a light source system according to the first signal feedback to the controller; and
irradiating the droplet by a drive laser to output a light beam from the light source system to the scanner system.

2. The lithography method of claim 1, wherein controlling the trajectory of the droplet comprises:
compensating, by the controller, a position change of a camera in the light source system according to the first signal; and
obtaining an image by the camera in the light source system;
wherein the trajectory of the droplet is controlled according to the image and the position change of the camera.

3. The lithography method of claim 2, wherein obtaining the image by the camera comprises:
generating, by a line laser module, a light curtain in a chamber of the light source system; and
imaging, by the camera, the light curtain as the droplet passing through the light curtain to obtain the image.

4. The lithography method of claim 2, wherein controlling the trajectory of the droplet comprises:
determining, by the controller, the trajectory of the droplet according to the image and the position change of the camera;
computing, by the controller, a droplet position error according to the trajectory of the droplet; and
outputting, by the controller, a driving signal in response to the droplet position error to drive a droplet generator in the light source system to steer the trajectory of the droplet.

5. The lithography method of claim 1, further comprising:
reflecting the light beam, by a field facet mirror in the scanner system, to the optical alignment sensor; and
detecting the light signal by one or more pinhole spots on the optical alignment sensor to generate the first signal.

6. The lithography method of claim 5, further comprising:
controlling, by the controller, the droplet passing through a primary focus position of a collector mirror in the light source system according to the light beam received by the one or more pinhole spots on the optical alignment sensor.

7. The lithography method of claim 6, further comprising:
controlling, by the controller, the light beam passing through an intermediate focus position of the collector mirror in the light source system according to the light beam received by one or more intermediate focus spots on the optical alignment sensor.

8. A lithography method, comprising:
obtaining an image by a camera in a light source system;
computing, by a controller, a position change of the camera, according to a light signal received by an optical alignment sensor in a scanner system; and
determining, by the controller, a trajectory of a droplet in the light source system according to the image and the position change of the camera.

9. The lithography method of claim 8, wherein obtaining the image comprises:
generating, by a line laser module, a light curtain in a chamber of the light source system; and
imaging, by the camera, the light curtain as the droplet passing through the light curtain to obtain the image.

10. The lithography method of claim 8, further comprising:
computing, by the controller, a droplet position error according to the trajectory of the droplet; and
outputting, by the controller, a driving signal in response to the droplet position error to drive a droplet generator in the light source system to steer the trajectory of the droplet.

11. The lithography method of claim 8, further comprising:
reflecting a light beam by a field facet mirror in the scanner system to the optical alignment sensor; and
detecting the light by one or more pinhole spots on the optical alignment sensor to generate the first signal.

12. The lithography method of claim 11, further comprising:
outputting, by the optical alignment sensor, a first signal to the controller in response to the light signal received by the optical alignment sensor; and
computing, by the controller, the position change of the camera, according to the first signal.

13. The lithography method of claim 11, further comprising:
controlling, by the controller, the droplet passing through a primary focus position of a collector mirror in the light source system according to the light beam received by the one or more pinhole spots on the optical alignment sensor.

14. The lithography method of claim 13, further comprising:
controlling, by the controller, the light beam passing through an intermediate focus position of the collector mirror in the light source system according to the light beam received by one or more intermediate focus spots on the optical alignment sensor.

15-20. (canceled)

21. A lithography method, comprising:
irradiating a droplet by a drive laser to output a light from a light source system to a scanner system for a predetermined time period;
obtaining an image by a camera in the chamber after the predetermined time period;
detecting the light, by an optical alignment sensor positioned out of the chamber, and producing a first signal according to the detected light; and
determining, by a controller, a position change of the camera, according to the first signal and adjusting a trajectory of the droplet according to the image and the position change of the camera.

22. The lithography method of claim 21, wherein obtaining the image comprises:
generating, by a line laser module, a light curtain in the chamber; and
imaging, by the camera, the light curtain as the droplet passing through the light curtain to obtain the image.

23. The lithography method of claim 21, wherein the adjustment of the trajectory of the droplet comprising:
computing, by the controller, a droplet position error according to the image and the position change of the camera; and
outputting, by the controller, a driving signal in response to the droplet position error to drive a droplet generator in the light source system to steer the trajectory of the droplet.

24. The lithography method of claim 21, further comprising:
reflecting the light from the light source system by a field facet mirror in the scanner system to the optical alignment sensor; and
detecting, by the optical alignment sensor, the light received by one or more pinhole spots on the optical alignment sensor to generate the first signal.

25. The lithography method of claim 21, further comprising:
controlling, by the controller, the droplet passing through a primary focus position of a collector mirror in the chamber according to the light received by one or more pinhole spots on the optical alignment sensor.

26. The lithography method of claim 25, further comprising:
controlling, by the controller, the light passing through an intermediate focus position of the collector mirror in the light source system according to the light received by one or more intermediate focus spots on the optical alignment sensor.
